(19) United States
(12) Patent Application Publication
(10) Pub. No.: US 2025/0239562 A1
(43) Pub. Date: Jul. 24, 2025

(54) BAKING SYSTEM FOR PROCESSING UNIT ASSEMBLY

(71) Applicant: ZT Group Int’l, Inc. dba ZT Systems, Secaucus, NJ (US)

(72) Inventors: Sruti Chigullapalli, Seattle, WA (US); Paul Anderson, Leander, TX (US); Daniel Kondracki, Nyack, NY (US)

(21) Appl. No.: 18/415,776

(22) Filed: Jan. 18, 2024

(51) Int. Cl. H01L 23/00; H05B 1/02

(52) U.S. Cl. CPC H01L 24/75; H01L 24/83; H05B 1/0233; H01L 2224/75272; H01L 2224/832

(57) ABSTRACT

A baking system is provided. A receiving base is operable to receive a processing unit assembly including a processing unit, a thermal solution, and a thermal interface material operable to couple the processing unit and the thermal solution. An upper portion is operable to provide heat to the processing unit assembly to cure the thermal interface material. The upper portion directs heat to the processing unit assembly from above the processing unit assembly. A bottom portion is operable to provide heat to the processing unit assembly to cure the thermal interface material. The bottom portion directs heat to the processing unit assembly from below the processing unit assembly opposite the upper portion.

### FIELD

The present disclosure relates generally to a baking system operable to cure thermal interface material to couple a processing unit with a thermal solution.

### BACKGROUND

Processing units such as graphics processing units (GPUs) bond with thermal solutions (e.g., heatsinks and/or cold plates) using a phase change thermal interface material. The smallest of voids in the thermal interface material can make a GPU throttle thermally which can result in a huge performance loss, for example at a cluster level artificial intelligence or machine learning workload.

### BRIEF DESCRIPTION OF THE DRAWINGS

Implementations of the present technology will now be described, by way of example only, with reference to the attached figures, wherein:

FIG. 1 illustrates a baking system for bonding a processing unit with a thermal solution;

FIG. 2A illustrates an exploded view of a processing unit assembly;

FIG. 2B illustrates an assembled view of the processing unit assembly;

FIG. 3 illustrates a cross-sectional diagram of the baking system;

FIG. 4A illustrates an upper portion of the baking system;

FIG. 4B illustrates the upper portion of the baking system;

FIG. 4C illustrates a cross-sectional diagram of the upper portion of the baking system;

FIG. 5A illustrates a bottom portion of the baking system;

FIG. 5B illustrates a cross-sectional view of the baking system;

FIG. 6A illustrates the baking assembly with a plurality of baking systems;

and

FIG. 6B illustrates the baking assembly of FIG. 6A.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented. The term “coupled” is defined as connected, whether directly or indirectly through intervening components, and is not necessarily limited to physical connections. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “about” means reasonably close to the particular value. For example, about does not require the exact measurement specified and can be reasonably close. As used herein, the word “about” can include the exact number. The term “near” as used herein is within a short distance from the particular mentioned object. The term “near” can include abutting as well as relatively small distance beyond abutting. The terms “comprising,” “including” and “having” are used interchangeably in this disclosure. The terms “comprising,” “including” and “having” mean to include, but not necessarily be limited to the things so described.

Processing units (e.g., GPUs) are bare-die and need a thermal interface material to bond with the thermal solution (e.g., heatsinks for air-cooled and cold plate for liquid-cooled) inside the corresponding computing system (e.g., personal computers, artificial intelligence/machine learning servers, etc.). Uneven melting and flow can be one of the biggest challenges in curing thermal interface material with full spreading and without voids. The thermal interface material can include a phase change material and needs an activation temperature of greater than 50 degrees Celsius to phase change, flow, and fill all the voids, thereby creating a perfect attachment between the die and the thermal solution, with lowest thermal resistance. This process can be particularly difficult to do with cold plates which can be filled with cold fluid at less than 40 degrees Celsius in liquid cooled computing systems.

Conventional processes for air-cooled heatsinks depend a lot on trial and error and can result in large variations in performance from processor unit assembly to processor unit assembly. Some of the culprits for the variations in performance can include thermal interface material voids, thermal interface material overflow, insufficient baking which can create a lot of quality issues not only at time zero but also later after deployment in the computing systems. Cold liquid for liquid cooled computing system only exacerbate the issues. All it takes is just one process unit throttling due to thermal issues to tank the performance of the entire processing unit cluster.

The presently disclosed baking system provides a more robust and repeatable setup for thermal interface material phase change and curing process for processing unit assemblies. The baking system provides an upper portion that forms a combination of an inner chamber and outer chamber for heating the thermal solution (e.g., cold plate and/or heatsink) from inside and above using an above-board heating element which can adjust the appropriate temperature and timing to get the tightest distribution for thermal interface material curing and resistance. In at least one example, when a plurality of processing unit assemblies are being baked in series, the thermal solution internal liquid connections can be joined in series to provide heated fluid directly to the thermal solution-to-thermal interface material surface area for even temperature distribution. This combination of locally directed temperature conditioning provides for even thermal interface material flow and distribution and lowest occurrence of voids.

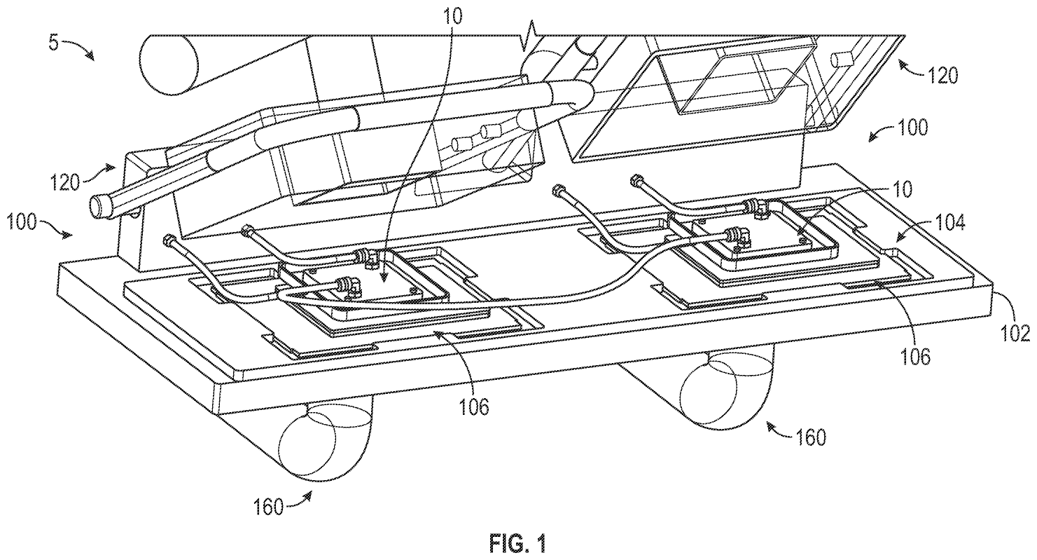

The disclosure now turns to FIG. 1, which illustrates an example of a baking system 100 that is operable to provide a precision curing process to evenly melt and/or flow a thermal interface material in a processing unit assembly 10. In some examples, as shown in FIG. 1, a plurality of baking systems 100 can be included in a system 5 to provide for an assembly line system where multiple baking systems 100 can bake and cure thermal interface material in a plurality of processing unit assemblies 10. While FIG. 1 illustrates a system 5 with two baking systems 100, in some examples, more than 2 baking systems 100 can be incorporated into a system 5. In some examples, only one baking system 100 can be utilized at a time. In some examples, a system 5 may include only one baking system 100.

The baking system 100 can include a receiving base 102 operable to receive the processing unit assembly 10. As illustrated in FIG. 1, the system 5 can include the receiving base 102 that is operable to form a surface 104 that can receive the baking system(s) 100. In some examples, the surface 104 and/or the receiving base 102 can form a receiving portion 106 (e.g., a first receiving portion 106 and a second receiving portion 106) for each of the baking systems 100. In some examples, the receiving portion(s) 106 can include a recess formed in the receiving base 102 of the system 5. In some examples, where the system 5 only includes one baking system 100, the receiving base 102 and the receiving portion 106 may be the same component. In some examples, the receiving base 102 may form only the one receiving portion 106.

An upper portion 120 can be operable to provide heat to the processing unit assembly 10 to cure the thermal interface material. In some examples, the upper portion 120 can be coupled with the receiving base 102. The upper portion 120 directs heat to the processing unit assembly 10 from above the processing unit assembly 10 opposite the receiving base 102. A bottom portion 160 of the baking system 100 can be operable to provide heat to the processing unit assembly 10 to cure the thermal interface material along with the upper portion 120. The bottom portion 160 directs heat to the processing unit assembly 10 from below the processing unit assembly 10 opposite the upper portion 120. In some examples, the bottom portion 160 can be coupled with the receiving base 102 and provides heat through the receiving base 102. In some examples, the bottom portion 160 can be coupled to the underside of the receiving base 102. Accordingly, the baking system 100, with the upper portion 120 and the bottom portion 160, provides heat simultaneously from above and below the processing unit assembly 10. This can ensure even temperature distribution for the best opportunity for even thermal interface material flow and distribution and lowest occurrence of voids.

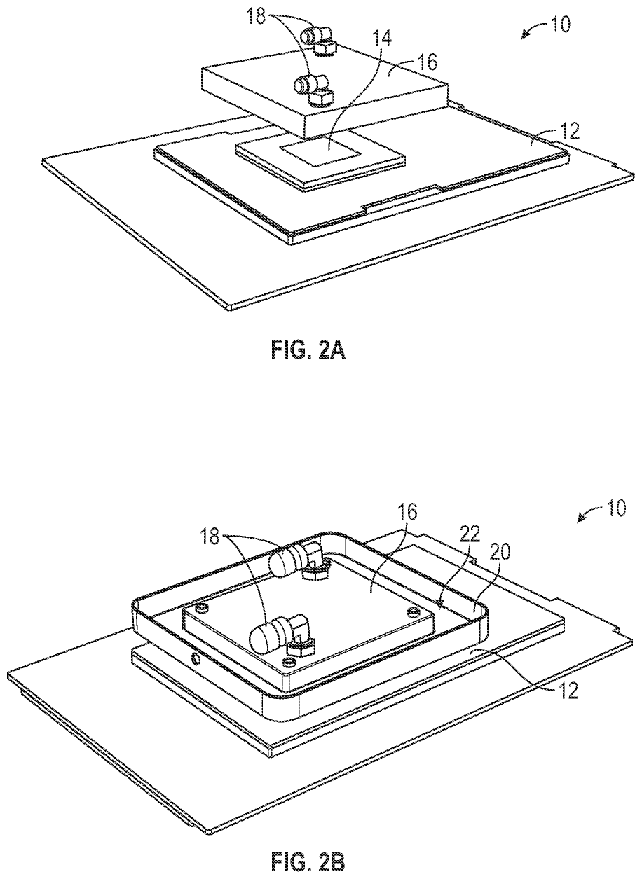

FIGS. 2A and 2B illustrate a processing unit assembly 10. The processing unit assembly 10 can include a processing unit 12, a thermal solution 16, and a thermal interface material 14. The thermal solution 16 can include, for example, a cold plate and/or a heatsink. The thermal solution 16 can be operable to manage the temperature of the processing unit 12 to prevent overheating and damage to the processing unit 12. In some examples, the thermal solution 16 can control the temperature of the processing unit 12 via fluids (e.g., water and/or coolant) and/or air flow. In some examples, the thermal solution 16 can include one or more fluid ports 18 operable to provide inlet and outlet flow of the fluid into the thermal solution 16 to manage the temperature of the processing unit 12.

The thermal interface material 14 can be operable to couple the processing unit 12 and the thermal solution 16. The thermal interface material 14 can be positioned between the processing unit 12 and the thermal solution 16. The thermal interface material 14 can be sandwiched between the processing unit 12 and the thermal solution 16. The thermal interface material 14 bonds the processing unit 12 with the thermal solution 16. The thermal interface material 14 can include a phase change material. The thermal interface material 14 can be activated at a temperature greater than 50 degrees Celsius to change phase, flow, and fill all the voids between the processing unit 12 and the thermal solution 16 to successfully create an attachment between the processing unit 12 and the thermal solution 16, with the lowest thermal resistance. In particular, filling the voids and providing low thermal resistance between the processing unit 12 and the thermal solution 16 can be difficult to do with cold plates that are filled with cold fluid at less than 40 degrees Celsius. The baking system 100 as disclosed herein can prevent curing issues such as voids, overflow, and/or insufficient baking which can create a lot of quality issues not only at time zero but also down the road after the processing unit assembly 10 is deployed in the computing systems. In some examples where the processing unit assembly 10 is utilized in data centers, one processing unit throttling due to thermal issues can tank the performance of the entire processing cluster.

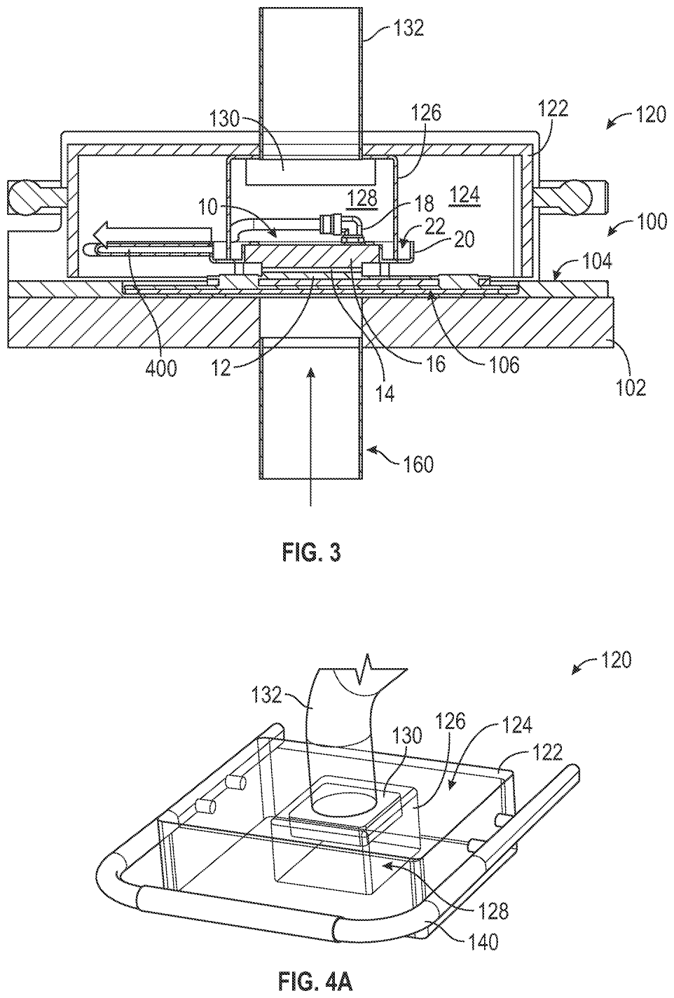

FIG. 3 illustrates the baking system 100 receiving the processing unit assembly 10 and curing the thermal interface material 14. As shown in FIG. 3, the processing unit assembly 10 is received in the receiving portion 106 of the receiving base 102. The upper portion 120 is positioned over the processing unit assembly 10 so that the upper portion 120 can direct heat towards the top of the processing unit assembly 10 (e.g., the top of the thermal solution 16). The bottom portion 160 is positioned underneath the processing unit assembly 10 so that the bottom portion 160 can direct heat to the underside of the processing unit assembly 10 opposite the upper portion 120.

In at least one example, as illustrated in FIG. 3, a fluid abatement component 20 can at least partially surround the thermal solution 16. The fluid abatement component 20 can be operable to prevent fluid from the thermal solution 16 (e.g., fluid leaking from the connection of a fluid conduit to the fluid ports 18) to flow across the fluid abatement component 20. Accordingly, the fluid abatement component 20 can be operable to contain the fluid that leaks from the thermal solution 16. In at least one example, the fluid abatement component 20 can form a channel 22 that is operable to receive the fluid. In some examples, as illustrated in FIG. 3, the fluid abatement component 20 can form a seal against the upper portion 120 to prevent fluid flow therethrough. For example, an inner enclosure 126 of the upper portion 120 can abut against the fluid abatement portion 20 to form a seal. An exhaust conduit 400 can be in fluid communication with the upper portion 120 and/or the fluid abatement component 20. The exhaust conduit 400 can be operable to remove any fluid contained by the fluid abatement component 22 from the baking system 100.

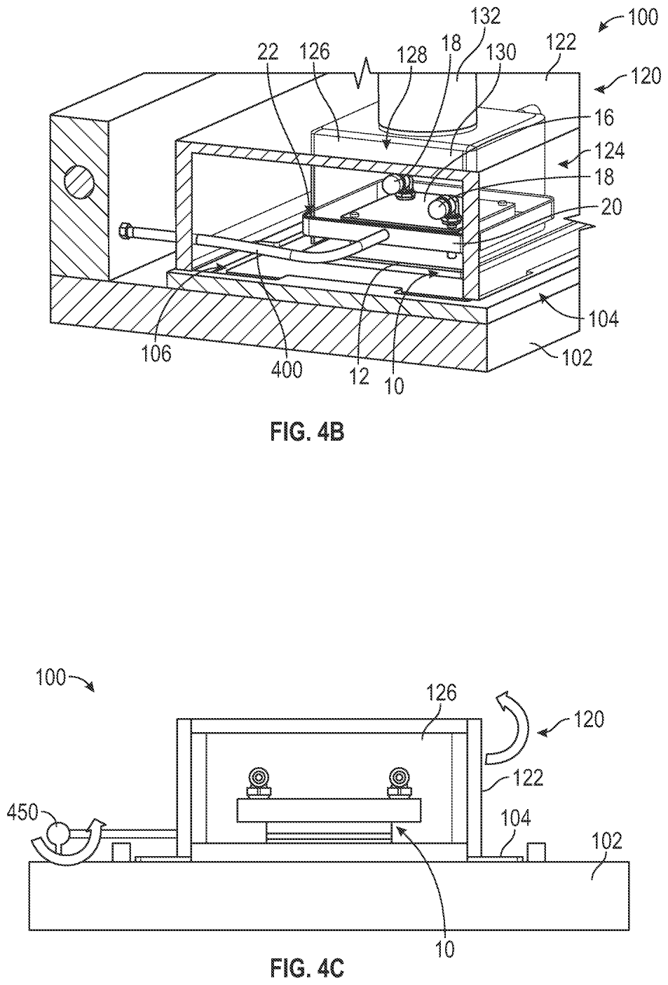

FIGS. 4A, 4B, and 4C illustrate the upper portion 120 of the baking system 100. The upper portion 120 can include an outer enclosure 122 that forms an outer chamber 124 operable to removably encase the processing unit assembly 10. The outer enclosure 122 can be positioned over the processing unit assembly 10 such that the outer enclosure abuts against the surface 104 of the receiving base 102. In some examples, the exhaust conduit 400 can be in communication with the upper portion 120 such that the exhaust conduit 400 is operable to provide evacuation of air, humidity, and/or liquid from the outer chamber 124. In some examples, the upper portion 120 can include a plurality of exhaust conduits 400 that can be in communication with any combination of the outer chamber 124, the fluid abatement component 20, and/or the inner chamber 128. The outer enclosure 122 can be operable to control the environment conditions (e.g., humidity, temperature, and/or contamination) surrounding the entire processing unit assembly 10. The exhaust conduit 400 can be operable to provide evacuation of heated air or liquid (for example greater than 50 degrees Celsius) from the outer chamber 124 to help control the environment around the processing unit assembly 10.

The upper portion 120 can also include an inner enclosure 126 that forms an inner chamber 128 operable to removably encase the processing unit assembly 10 and also is encased in the outer chamber 124 of the outer enclosure 122. The inner enclosure 126 is contained within the outer enclosure 122. The inner enclosure 126 can be operable to provide local temperature control for the processing unit assembly 10, for example the thermal solution 16. As discussed above, in some examples, the inner enclosure 126 can abut against the fluid abatement component 20 and/or the receiving base 102 to form a seal to prevent fluid flow therethrough. Accordingly, any fluid that leaks can be captured by the inner enclosure 126 and, in some examples, removed by the exhaust conduit 400.

The inner enclosure 126 can include an above-board heating element 130 operable to provide heat to the processing unit assembly 10 from above. The above-board heating element 130 can be operable to convert electrical energy into heat through resistance. For example, a power conduit 132 can extend into the inner chamber 126 and be in communication with the above-board heating element 130. The above-board heating element 130 can receive electrical power from the power conduit 132 and convert the electrical energy into heat through resistance.

In at least one example, as illustrated in FIG. 4C, the upper portion 120 can be pivotably coupled with the receiving base 102 such that the upper portion 120 is pivotably positioned over the processing unit assembly 10. For example, the upper portion 120 can pivot about a pivot point 450 to be lifted or lowered over the processing unit assembly 10 as needed. In at least one example, the upper portion 120 can include a handle 140 (as shown in FIG. 4A) that can be used for lifting and/or lowering the upper portion 120 as the upper portion 120 pivots about the pivot point 450.

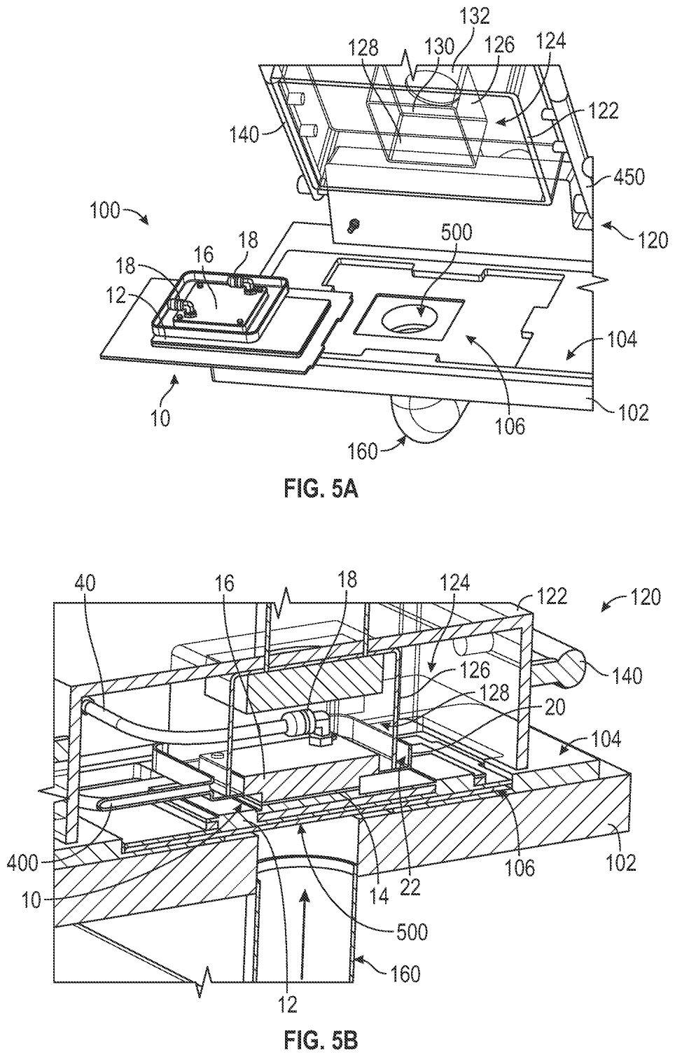

FIGS. 5A and 5B illustrate the bottom portion 160 of the baking system 100. The bottom portion 160 is operable to provide heated air to the processing unit assembly 10 from below. The bottom portion 160 can be in communication with the receiving base 102, for example the receiving portion 106 of the receiving base 102. In at least one example, the bottom portion 160 can form a conduit that can direct heated air towards the processing unit assembly 10 from below. In at least one example, as shown in FIGS. 5A and 5B, the receiving base 102 can form an inlet aperture 500 in fluid communication with the bottom portion 160 such that the heated air from the bottom portion 160 flows towards the processing unit assembly 10 from below through the inlet aperture 500. Accordingly, the processing unit assembly 10 can be positioned on top of and across the inlet aperture 500 such that the heated air from the bottom portion 160 flows across the bottom of the processing unit assembly 10 (e.g., the processing unit 12).

In at least one example, the upper portion 120 (e.g., the above-board heating element 130) and the bottom portion 160 with the heated air can be preset with temperatures and timing for a bake recipe to control thermal interface material 14 phase change and distribution. In some examples, the processing unit 12 with a solid thermal interface material 14 can be pre-baked. Having a controlled pre-bake can reduce risk of incomplete flow during workload.

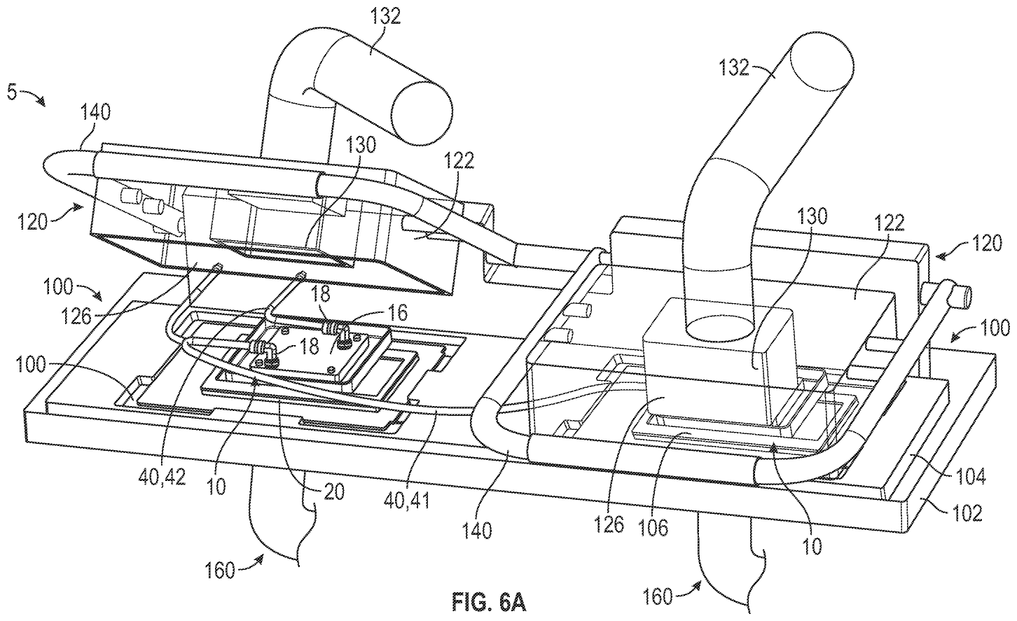

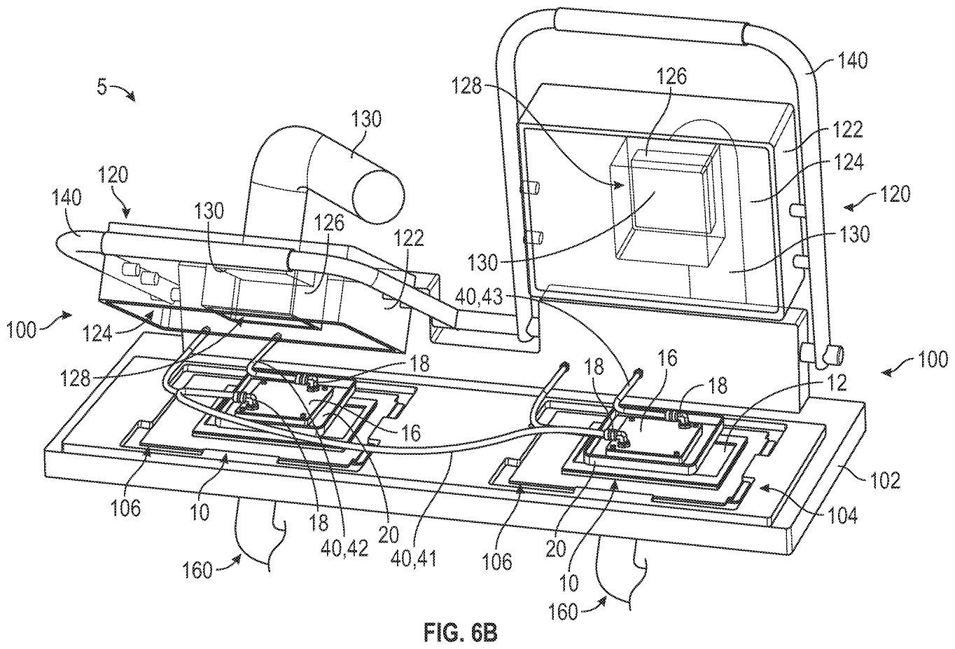

FIGS. 6A and 6B illustrate the system 5 that includes a plurality of baking systems 100. The receiving base 102 of the system can form a first receiving portion 106 and a second receiving portion 106 to receive a first processing unit assembly 10 and a second processing unit assembly 10, respectively. While FIGS. 6A and 6B illustrate the system 5 including two baking systems 100, in other examples, more than two baking systems 100 can be accommodated. The first receiving portion 106 and the second receiving portion 106 can be in series. Accordingly, the baking systems 100 can cure the thermal interface material 14 for two processing unit assemblies 10 at the same time and/or in assembly line format to expedite the process. For example, the first processing unit assembly 10 may be pre-baked in the first baking system 100 and then moved to the second baking system 100 to flow the thermal interface material 14 throughout the interface. Meanwhile, a second processing unit assembly 10 is positioned into the first baking system 100 to be pre-baked.

In at least one example, as shown in FIGS. 6A and 6B, the first thermal solution 16 of the first processing unit assembly 10 can be connected to the second thermal solution 16 of the second processing unit 10 via one or more thermal solution internal liquid connections 40. The thermal solution internal liquid connections 40 can join the first thermal solution 16 and the second thermal solution 16 in series to provide heated fluid to the first thermal solution 16 and the second thermal solution 16. The heated fluid is then provided directly to the interface between the thermal solution 16 and the thermal interface material 14 for even temperature distribution. The combination of locally directed temperature conditioning can provide for the best opportunity for even thermal interface material flow and distribution and lowest occurrence of voids. For example, a first thermal solution internal liquid connection 42 can provide fluid to the first thermal solution 16. A second thermal solution internal liquid connection 41 can provide fluid that has flowed through the first thermal solution 16 to the second thermal solution 16. A third thermal solution internal liquid connection 43 can remove the fluid from the second thermal solution 16. In some examples, the fluid from the third thermal solution internal liquid connection 43 can be recycled to flow back into the first thermal solution internal liquid connection 42.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure to the full extent indicated by the broad general meaning of the terms used in the attached claims. It will therefore be appreciated that the embodiments described above may be modified within the scope of the appended claims.

What is claimed is:

1. A baking system comprising:
a receiving base operable to receive a processing unit assembly including a processing unit, a thermal solution, and a thermal interface material operable to couple the processing unit and the thermal solution;
an upper portion operable to provide heat to the processing unit assembly to cure the thermal interface material, wherein the upper portion directs heat to the processing unit assembly from above the processing unit assembly; and
a bottom portion operable to provide heat to the processing unit assembly to cure the thermal interface material, wherein the bottom portion directs heat to the processing unit assembly from below the processing unit assembly opposite the upper portion.

2. The baking system of claim 1, wherein the upper portion includes an outer enclosure that forms an outer chamber operable to removably encase the processing unit assembly.

3. The baking system of claim 2, wherein the outer enclosure is operable to control environmental conditions surrounding the processing unit assembly.

4. The baking assembly of claim 2, further comprising an exhaust conduit in communication with the upper portion, the exhaust conduit operable to provide evacuation of air, humidity, and/or liquid from the outer chamber.

5. The baking system of claim 2, wherein the upper portion includes an inner enclosure that forms an inner chamber operable to removably encase the processing unit assembly and be encased in the outer chamber of the outer enclosure.

6. The baking system of claim 5, wherein the inner enclosure includes an above-board heating element operable to provide the heat to the processing unit assembly from above, wherein the above-board heating element is operable to convert electrical energy into heat through resistance.

7. The baking system of claim 5, further comprising a fluid abatement component surrounding the thermal solution, the fluid abatement component operable to contain fluid that leaks from the thermal solution.

8. The baking system of claim 7, wherein the inner enclosure abuts against the fluid abatement component to form a seal.

9. The baking system of claim 1, wherein the upper portion is pivotably coupled to the receiving base such that the upper portion is pivotably positionable over the processing unit assembly.

10. The baking system of claim 1, wherein the bottom portion is arranged to provide heated air to the processing unit assembly from below.

11. The baking assembly of claim 10, wherein the receiving base forms an inlet aperture in fluid communication with the bottom portion such that the heated air from the bottom portion flows towards the processing unit assembly from below through the inlet aperture.

12. A system comprising:
a processing unit assembly including a processing unit, a thermal solution, and a thermal interface material operable to couple the processing unit and the thermal solution; and
a baking system including:
a receiving base operable to receive the processing unit assembly;
an upper portion operable to provide heat to the processing unit assembly to cure the thermal interface material, wherein the upper portion directs heat to the processing unit assembly from above the processing unit assembly; and
a bottom portion operable to provide heat to the processing unit assembly to cure the thermal interface material, wherein the bottom portion directs heat to the processing unit assembly from below the processing unit assembly opposite the upper portion.

13. The system of claim 12, wherein the upper portion includes an outer enclosure, wherein when the upper portion is positioned over the processing unit assembly to provide the heat, the outer enclosure encases the processing unit assembly.

14. The system of claim 13, wherein the upper portion includes an inner enclosure received in the outer enclosure, wherein when the upper enclosure is positioned over the processing unit assembly to provide the heat, the inner enclosure encases the processing unit assembly.

15. The system of claim 14, wherein the upper portion includes an above-board heating element received in the inner enclosure, the above-board heating element operable to provide the heat to the processing unit assembly, wherein when the upper portion is positioned over the processing unit assembly to provide the heat, the above-board heating element is positioned above the processing unit assembly.

16. The system of claim 15, wherein the above-board heating element is operable to convert electrical energy into heat through resistance.

17. The system of claim 12, wherein the bottom portion is arranged to direct heated air to the processing unit assembly.

18. A method comprising:
receiving, by a receiving base of a baking system, a processing unit assembly which includes a processing unit, a thermal solution, and a thermal interface material operable to couple the processing unit and the thermal solution;
providing heat, by an upper portion of the baking system, to the processing unit assembly from above the processing unit assembly to cure the thermal interface material; and
providing heat, by a bottom portion of the baking system, to the processing unit assembly from below the processing unit assembly to cure the thermal interface material.

19. The method of claim 18, further comprising:
providing, by an exhaust conduit in communication with the upper portion, evacuation of air, humidity, and/or liquid from the baking system.

20. The method of claim 18, wherein when the upper portion provides the heat from above, an above-board heating element converts electrical energy into heat through resistance, and wherein when the bottom portion provides the heat from below, the bottom portion directs heated air to the processing unit assembly.
